(19) United States
(12) Patent Application Publication
(10) Pub. No.: US 2026/0082972 A1
(43) Pub. Date: Mar. 19, 2026

(54) SYSTEMS FOR BONDING A SEMICONDUCTOR ELEMENT TO A SUBSTRATE USING REDUCING GAS AND RELATED METHODS

(71) Applicant: Kulicke and Soffa Industries, Inc., Fort Washington, PA (US)

(72) Inventors: Dhiraj Muthyala, Ambler, PA (US); Timothy Paul Grant, Ambler, PA (US); Thomas J. Palumbo, Ambler, PA (US); Matthew Tarabulski, Ambler, PA (US)

(73) Assignee: Kulicke and Soffa Industries, Inc., Fort Washington, PA (US)

(21) Appl. No.: 19/328,377

(22) Filed: Sep. 15, 2025

Related U.S. Application Data
(60) Provisional application No. 63/695,044, filed on Sep. 16, 2024.

(51) Int. Cl. H01L 23/00

(52) U.S. Cl. CPC H10W 72/0711; H10W 72/072; H10W 72/016; H10W 72/07125; H10W 72/07232

(57) ABSTRACT

A bonding system for bonding a semiconductor element to a substrate is provided. The bonding system includes a bond head assembly including a bonding tool configured for bonding the semiconductor element to the substrate. The bonding system also includes a reducing gas delivery system for providing a reducing gas to a bonding area of the bonding system. The reducing gas delivery system includes a manifold. The manifold includes a lower surface defining (i) a reducing gas port for providing the reducing gas to the bonding area, and (ii) an exhaust port for removing a reaction product from the bonding area.

### CROSS REFERENCE TO RELATED APPLICATION

This application claims the benefit of U.S. Provisional Application No. 63/695,044, filed on Sep. 16, 2024, the content of which is incorporated herein by reference.

### FIELD

The invention relates to bonding systems and processes, and more particularly, to improved systems and methods for bonding a semiconductor element to a substrate using reducing gas.

### BACKGROUND

Traditional semiconductor packaging typically involves die attach processes and wire bonding processes. Advanced semiconductor packaging technologies (e.g., flip chip bonding, thermocompression bonding, etc.) continue to gain traction in the industry. For example, in thermocompression bonding (i.e., TCB), heat and/or pressure (and sometimes ultrasonic energy) are used to form a plurality of interconnections between (i) electrically conductive structures on a semiconductor element and (ii) electrically conductive structures on a substrate.

In certain flip chip bonding or thermocompression bonding applications, the electrically conductive structures of the semiconductor element and/or the substrate may include copper structures (e.g., copper pillars) or other material(s) that is subject to oxidation and/or other contamination. In such applications, it is desirable to provide an environment suitable for bonding. Conventionally, such an environment may be provided by using a reducing gas at the bonding area to reduce potential oxidation and/or contamination of the electrically conductive structures of the semiconductor element or the substrate to which it will be bonded.

Example patents and patent applications related to such a reducing gas environment include: U.S. Pat. No. 10,861,820 (entitled “METHODS OF BONDING SEMICONDUCTOR ELEMENTS TO A SUBSTRATE, INCLUDING USE OF A REDUCING GAS, AND RELATED BONDING MACHINES”); U.S. Pat. No. 11,205,633 (entitled “METHODS OF BONDING OF SEMICONDUCTOR ELEMENTS TO SUBSTRATES, AND RELATED BONDING SYSTEMS”); U.S. Pat. No. 11,515,286 (entitled “METHODS OF BONDING OF SEMICONDUCTOR ELEMENTS TO SUBSTRATES, AND RELATED BONDING SYSTEMS”); U.S. Patent Application Publication No. 2023/0133526 (entitled “BONDING SYSTEMS FOR BONDING OF SEMICONDUCTOR ELEMENTS TO SUBSTRATES, AND RELATED METHODS”); U.S. Patent Application Publication No. 2023/0260953 (entitled “METHODS OF MONITORING GAS BYPRODUCTS OF A BONDING SYSTEM, AND RELATED MONITORING SYSTEMS AND BONDING SYSTEMS”); U.S. Pat. No. 12,062,636 (entitled “BONDING SYSTEMS, AND METHODS OF PROVIDING A REDUCING GAS ON A BONDING SYSTEM”); and U.S. Patent Application Publication No. 2024/0063169 (entitled “BONDING SYSTEMS FOR BONDING A SEMICONDUCTOR ELEMENT TO A SUBSTRATE, AND RELATED METHODS”). These references are incorporated by reference herein in their entirety.

Thus, it would be desirable to provide improved methods of bonding semiconductor elements to a substrate with the use of a reducing gas.

### SUMMARY

According to an exemplary embodiment of the invention, a bonding system for bonding a semiconductor element to a substrate is provided. The bonding system includes a bond head assembly including a bonding tool configured for bonding the semiconductor element to the substrate. The bonding system also includes a reducing gas delivery system for providing a reducing gas to a bonding area of the bonding system, the reducing gas delivery system including a manifold, the manifold including a lower surface defining (i) a reducing gas port for providing the reducing gas to the bonding area, and (ii) an exhaust port for removing a reaction product from the bonding area.

According to another exemplary embodiment of the invention, a reducing gas delivery system of a bonding system is provided. The reducing gas delivery system includes a manifold for (i) providing a reducing gas to a bonding area of the bonding system and (ii) removing reaction products from the bonding area of the bonding system, the manifold including a lower surface. The reducing gas delivery system also includes a reducing gas port for delivering the reducing gas to the bonding area, the reducing gas port being at least partially defined by a lower surface of the manifold. The reducing gas delivery system also includes an exhaust port for removing reaction products from the bonding area during the bonding operation, the exhaust port being at least partially defined by the lower surface of the manifold.

According to other embodiments of the invention, the bonding system and/or the reducing gas delivery system recited in the immediately two preceding paragraphs may have any one or more of the following features: the reducing gas port is on an opposite side of the lower surface from the exhaust port; the lower surface defines a plurality of reducing gas ports for providing the reducing gas to the bonding area, the reducing gas port being one of the plurality of reducing gas ports; the plurality of reducing gas ports are on an opposite side of the lower surface from the exhaust port; one of the plurality of reducing gas ports is located on an opposite side of the lower surface from another of the plurality of reducing gas ports; the exhaust port is adjacent to at least one of the plurality of reducing gas ports; the plurality of reducing gas ports are arranged on three sides of an opening defined by the lower surface, and the exhaust port is located on a fourth side of the opening; the plurality of reducing gas ports are arranged along a line; the plurality of reducing gas ports are arranged along a curve; the lower surface defines a plurality of exhaust ports for removing reaction products from the bonding area, the exhaust port being one of the plurality of exhaust ports; the reducing gas port is located on a corner of the lower surface; the exhaust port is located on another corner of the lower surface; the reducing gas delivery system is integrated with the bond head assembly; the manifold defines an opening to accommodate the bonding tool; the manifold includes an angled surface proximate to the reducing gas port for directing flow of the reducing gas; the manifold defines at least one groove proximate to the reducing gas port for steering the reducing gas inside of the manifold; the manifold defines at least one protrusion proximate to the reducing gas port for steering the reducing gas inside of the manifold; the lower surface defines at least one groove for steering the reducing gas; the lower surface defines at least one protrusion for steering the reducing gas; the lower surface defines a concave shape; the lower surface defines a convex shape; the lower surface defines a plurality of dimples for developing turbulent flow of the reducing gas; and the reducing gas delivery system defines a shielding gas port for containing the reducing gas at the bonding area with a shielding gas.

According to another exemplary embodiment of the invention, a method of bonding a semiconductor element to a substrate on a bonding system is provided. The method includes the steps of (a) providing a reducing gas to a bonding area of a bonding system using a reducing gas delivery system, the reducing gas delivery system including a manifold, the manifold including a lower surface that defines a reducing gas port for providing the reducing gas to the bonding area; (b) bonding a semiconductor element to a substrate using a bonding tool of the bonding system; and (c) removing reaction products from the bonding area using an exhaust port of the manifold, the exhaust port being defined by the lower surface of the manifold.

According to other embodiments of the invention, the method recited in the immediately preceding paragraph may have any one or more of the following features: step (a) includes providing the reducing gas to the bonding area in a state of turbulent flow, the state of turbulent flow being induced by a plurality of dimples defined by the lower surface; a step of ejecting a shielding gas from the manifold during step (a) to contain the reducing gas at the bonding area with the shielding gas; steps (a) and (b) at least partially overlap one another in time; steps (a), (b), and (c) at least partially overlap one another in time; step (a) occurs prior to step (b); the reducing gas port is positioned on an opposite side of the lower surface from the exhaust port, and steps (a) and (c) occur simultaneously, such that during step (a) the reducing gas is directed across the bonding area; and step (a) includes providing the reducing gas to the bonding area via a plurality of reducing gas ports defined by the lower surface, the reducing gas port being one of the plurality of reducing gas ports, one of the plurality of reducing gas ports being located on an opposite side of the lower surface from another of the plurality of reducing gas ports.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity.

FIG. 1 is a block diagram illustration of a bonding system for bonding a semiconductor element to a substrate in accordance with an exemplary embodiment of the invention;

FIGS. 2-3 are bottom views of manifolds in accordance with various exemplary embodiments of the invention;

FIGS. 4-6 are perspective views of manifolds in accordance with various exemplary embodiments of the invention;

FIGS. 7-8 are bottom views of manifolds in accordance with various exemplary embodiments of the invention;

FIGS. 9-10 are perspective views of manifolds in accordance with various exemplary embodiments of the invention;

FIGS. 11-13 are bottom views of manifolds in accordance with various exemplary embodiments of the invention;

FIGS. 14-15 are perspective views of manifolds in accordance with various exemplary embodiments of the invention;

FIGS. 16-19 are bottom views of a manifold in accordance with various exemplary embodiments of the invention;

FIGS. 20A-20E are various views of a manifold in accordance with exemplary embodiments of the invention;

FIG. 21A is a bottom view of a manifold in accordance with yet another exemplary embodiment of the invention;

FIG. 21B is a detailed view of a portion of FIG. 21A;

FIGS. 22-23 are bottom views of manifolds in accordance with various exemplary embodiments of the invention;

FIGS. 24-25 are partial cross sectional side views of manifolds in accordance with various exemplary embodiments of the invention;

FIGS. 26A-26B are cross sectional side views of various manifolds in accordance with exemplary embodiments of the invention; and

FIG. 27 is a flow diagram illustrating methods of bonding a semiconductor element to a substrate on a bonding system in accordance with various exemplary embodiments of the invention.

### DETAILED DESCRIPTION

As used herein, the term “semiconductor element” is intended to refer to any structure including (or configured to include at a later step) a semiconductor chip or die. Exemplary semiconductor elements include a bare semiconductor die, a semiconductor die on a substrate (e.g., a leadframe, a PCB, a carrier, a semiconductor chip, a semiconductor wafer, a BGA substrate, a semiconductor element, etc.), a packaged semiconductor device, a flip chip semiconductor device, a die embedded in a substrate, a stack of semiconductor die, amongst others. Further, the semiconductor element may include an element configured to be bonded or otherwise included in a semiconductor package (e.g., a spacer to be bonded in a stacked die configuration, a substrate, etc.).

As used herein, the term “substrate” is intended to refer to any structure to which a semiconductor element may be bonded. Exemplary substrates include, for example, a leadframe, a PCB, a carrier, a module, a semiconductor chip, a semiconductor wafer, a BGA substrate, another semiconductor element, etc.

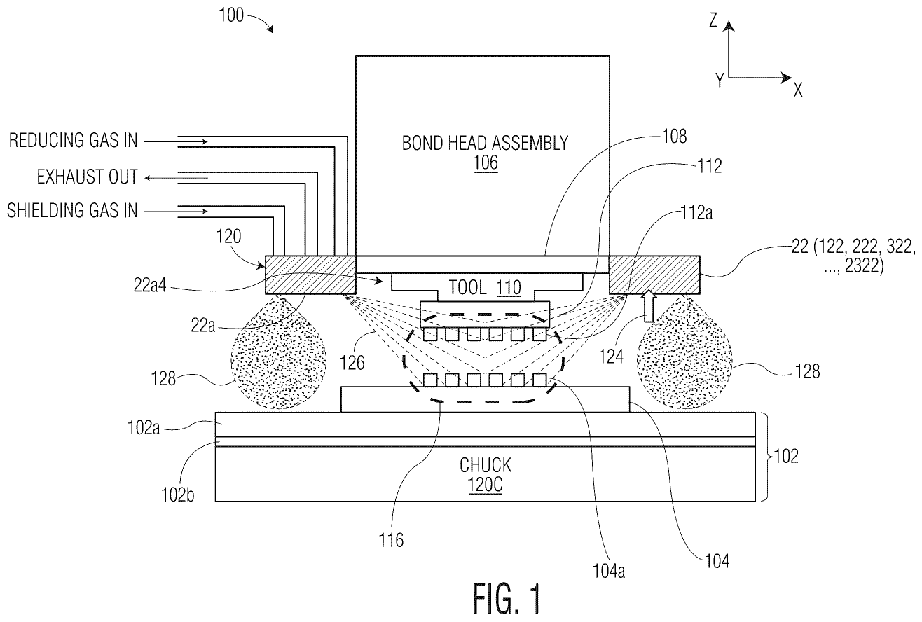

Referring now to FIG. 1, a bonding system 100 includes a support structure 102 for supporting a substrate 104 during a bonding operation. Support structure 102 may include any appropriate structure for a particular application. In the illustrated embodiment, support structure 102 includes a top plate 102a, a chuck 102c, and a heater 102b disposed therebetween. Top plate 102a directly supports substrate 104.

Bonding system 100 also includes a bond head assembly 106. Bond head assembly 106 includes a bonding tool 110 configured for bonding a semiconductor element 112 to substrate 104. Bond head assembly 106 may include any appropriate structure for a particular application. In the illustrated embodiment, bond head assembly 106 includes and/or carries a heater 108 for heating bonding tool 110, which in turn may heat semiconductor element 112. Bond head assembly 106 may be configured to move along (and about) a plurality of axes of bonding system 100 (e.g., an x-axis, a y-axis, a z-axis, a theta/rotative axis, etc.).

In connection with a bonding operation, semiconductor element 112 is bonded to substrate 104 using bonding tool 110. During the bonding operation, conductive structures 112a of semiconductor element 112 are bonded to respective conductive structures 104a of substrate 104 (e.g., using heat, force, ultrasonic energy, etc.).

Bonding system 100 includes a reducing gas delivery system 120 for providing a reducing gas 126 to a bonding area 116 of bonding system 100. In certain applications (e.g., thermocompression bonding, flip chip bonding, etc.), it is desirable to provide an environment suitable for bonding at the bonding area. Such an environment may be provided by using a reducing gas at the bonding area to reduce potential oxides of the conductive structures of the semiconductor element and/or the substrate to which it will be bonded. Bonding area 116 includes the space between bonding tool 110 and support structure 102 that accommodates conductive structures 104a/112a. However, it is contemplated that a bonding area could include additional space (e.g., space that accommodates substrate 104 and/or semiconductor element 112, etc.) without departing from the scope of the invention.

Reducing gas delivery system 120 includes a manifold 22 (e.g., where manifold 22 could be any of manifold 122, 222, 322, . . . , 2322 described herein, or any other manifold within the scope of the invention). Manifold 22 receives and distributes fluids as desired in a given application. In particular, manifold 22 receives reducing gas 126, a shielding gas 128, and an exhaust 124. Reducing gas 126 may be provided to manifold 22 from a reducing gas source (not illustrated), such as a bubbler, a tank, etc. Shielding gas 128 may similarly be provided to manifold 22 from a shielding gas source (not illustrated). Exhaust 124 may be drawn away from bonding area 116 using vacuum from a vacuum source (not illustrated). Reducing gas 126 may be any gas that includes reducing species, e.g., formic acid vapor. Shielding gas 128 may be any inert gas, such as nitrogen gas and may be used to provide an inert environment to reduce additional oxides from forming on the conductive structures. Shielding gas 128 may aid in containing the reducing gas and reaction products. Exhaust 124 includes reaction products resulting from applying reducing gas 126 to bonding area 116. Reaction products may include reducing gas, inert gas, surface oxides, any substances resulting from the reaction between the reducing gas and the surface oxides, and/or any other substances removed from conductive structures 104a/112a.

Various embodiments of manifold 22 are described herein. Each embodiment described includes common features. In particular, each manifold includes a lower surface 22a (e.g., wherein each embodiment has a lower surface 122a, 222a, 322a, . . . , 2322a). Lower surface 22a defines a reducing gas port for providing reducing gas 126 to bonding area 116. Lower surface 22a also defines an exhaust port for removing exhaust (e.g., reaction products) from bonding area 116. Exemplary manifolds may include a shielding gas port for providing shielding gas to or around the bonding area. Exemplary manifolds may further include an opening (e.g., see opening 22a4 in FIG. 1, and openings 122a4, 222a4, 322a4, etc.) to accommodate the bonding tool and/or the semiconductor element according to a particular application, allowing the reducing gas delivery system to be integrated with the bond head.

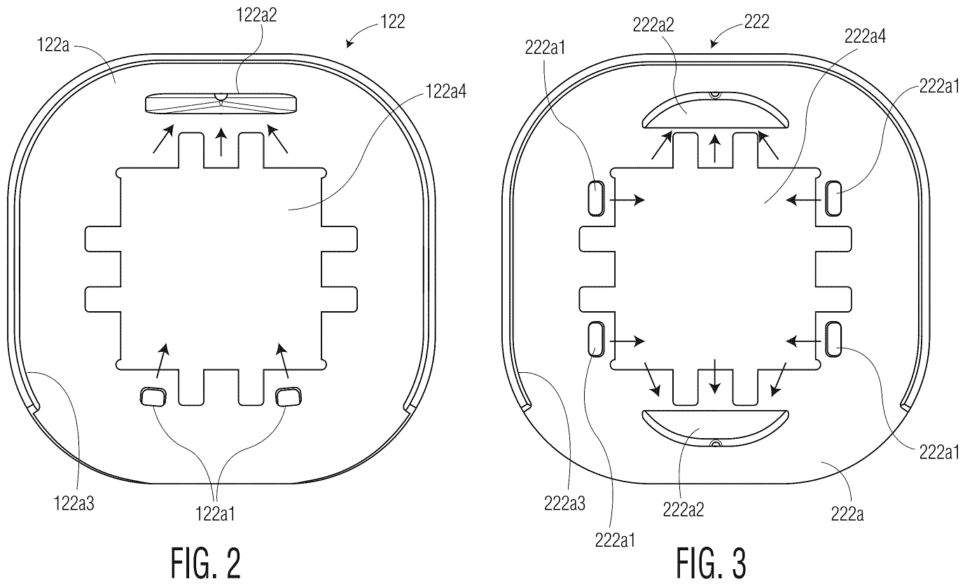

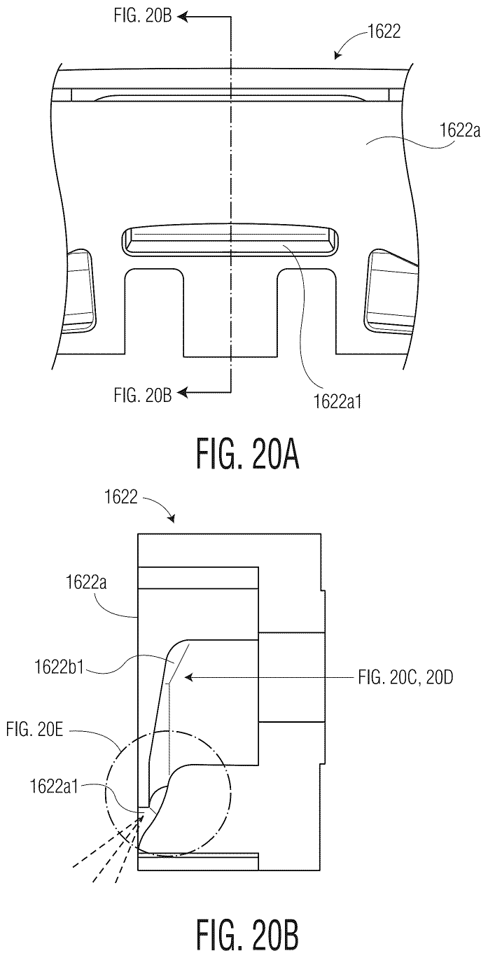

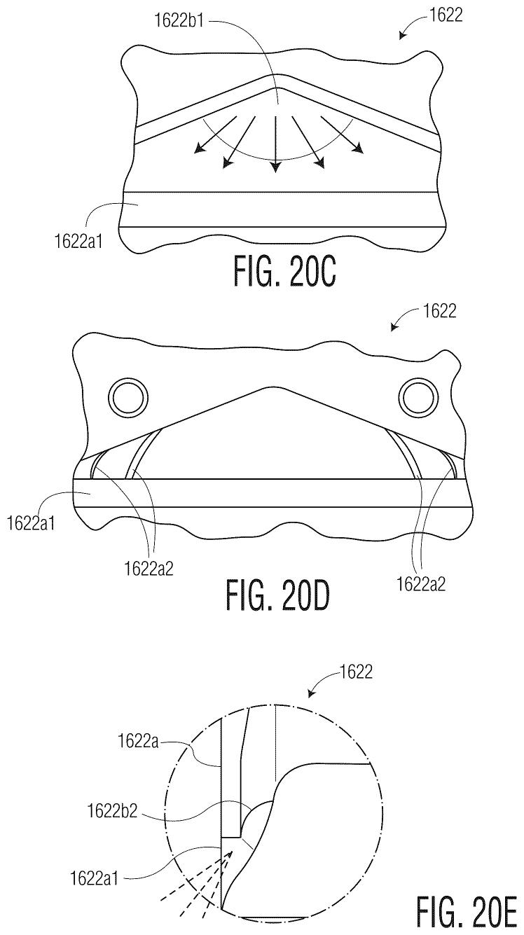

Each reducing gas port, shielding gas port, and exhaust port illustrated and described herein includes an opening configured to allow a fluid to pass through the port and into/out from a manifold (e.g., manifold 22 in FIG. 1). A reducing gas enters a manifold via a reducing gas inlet (e.g., see “REDUCING GAS IN” in FIG. 1), travels through a gas pathway (e.g., piping, channels, etc.) within the manifold, and exits the manifold at a reducing gas port(s). A shielding gas enters a manifold via a shielding gas inlet (e.g., see “SHIELDING GAS IN” in FIG. 1), travels through a gas pathway (e.g., piping, channels, etc.) within the manifold, and exits the manifold at a shielding gas port(s). Exhaust enters a manifold from the bonding area at an exhaust port(s), travels through a gas pathway (e.g., piping, channels, etc.) within the manifold (e.g., using vacuum), and exits the manifold (e.g., see “EXHAUST OUT” in FIG. 1). While various ports are illustrated and described herein, it is understood that a port may have any shape without departing from the scope of the invention. Various arrangements of ports are described herein (e.g., with respect to FIGS. 2-15). Additionally, various attributes and structures for guiding fluid flow at or near ports are described herein (e.g., with respect to FIGS. 20-26). Throughout the drawings, arrows are used to indicate the direction of flow of fluid (e.g., reducing gas, exhaust, shielding gas) to more clearly illustrate which structures are reducing gas ports, which are exhaust ports, and the presence of shielding gas ports.

Referring to FIG. 2, a manifold 122 is illustrated. Manifold 122 includes a lower surface 122a. Lower surface 122a defines a plurality of reducing gas ports 122a1, an exhaust port 122a2, a shielding gas port 122a3, and an opening 122a4. Manifold 122 includes a “straight across flow” configuration, wherein the plurality of reducing gas ports 122a1 is on an opposite side of the lower surface from exhaust port 122a2. In a straight across configuration, exhaust port 122a2 may draw reducing gas across the bonding area (e.g., via vacuum), which may promote recapture of reducing gas and/or exhaust.

Although manifold 122 is illustrated as having a shape approximating a square, the invention is not limited. It is contemplated that a manifold could have any shape (e.g., circular, rectangular, ovular, polygonal, etc.). As such, “opposite side” is not intended to limit the shape of the manifold. “Opposite side” is intended to be interpreted broadly. For example, “opposite side” with respect to a circular manifold would be understood to mean approximately diametrically opposed. Further, “opposite side” is not intended to limit the invention to exactly opposite, as it is contemplated that it may be desirable to place a reducing gas port at a position opposite but offset from the exhaust port.

FIG. 3 illustrates a manifold 222. Manifold 222 includes a lower surface 222a. Lower surface 222a defines a plurality of reducing gas ports 222a1, a plurality of exhaust ports 222a2, a shielding gas port 222a3, and an opening 222a4. Manifold 222 includes an “impinging flow” configuration, wherein at least one of the plurality of reducing gas ports 222a1 is located on an opposite side of the lower surface from another of the plurality of reducing gas ports 222a1. In particular, manifold 222 defines two of the plurality of reducing gas ports 222a1 on an opposite side of the lower surface from another two of the plurality of reducing gas ports 222a1. Each of the plurality of exhaust ports 222a2 are adjacent to two of the plurality of reducing gas ports 222a1. In an impinging flow configuration, high concentrations of reducing gas may be obtained at the bonding area of the bonding system.

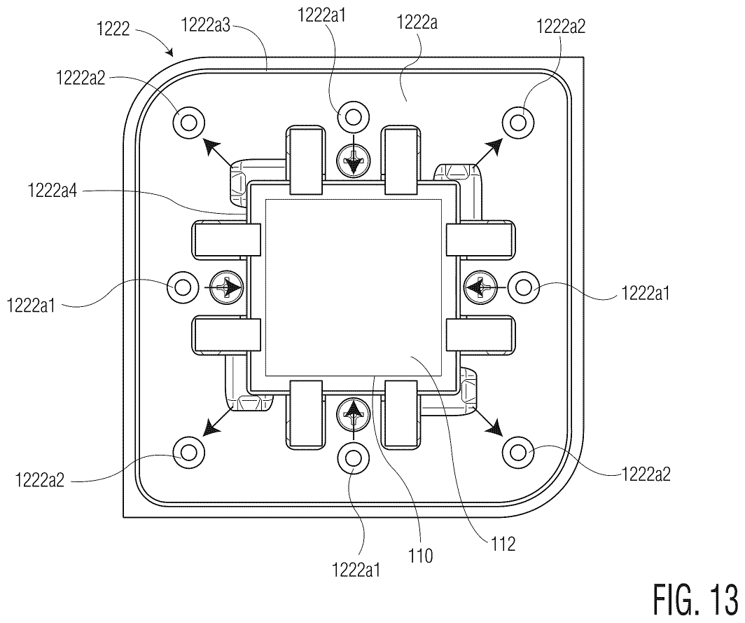

“Adjacent” is intended to be interpreted broadly. In the context of FIG. 3 (i.e., an approximately square shaped manifold), “adjacent” means on an adjacent side of the lower surface (i.e., an adjacent side of the square shape). For example, exhaust port 222a2 is adjacent a reducing gas port 222a1 to its left (as illustrated in FIG. 3), and adjacent another reducing gas port 222a1 to its right. However, the invention is not limited to such (e.g., in the case of a circular manifold, adjacent could mean within a certain circumferential distance, within a certain angle, etc.). It is contemplated that “adjacent” could refer to a space immediately proximate (“next to”) to a reference location (e.g., see FIGS. 13-15, described herein).

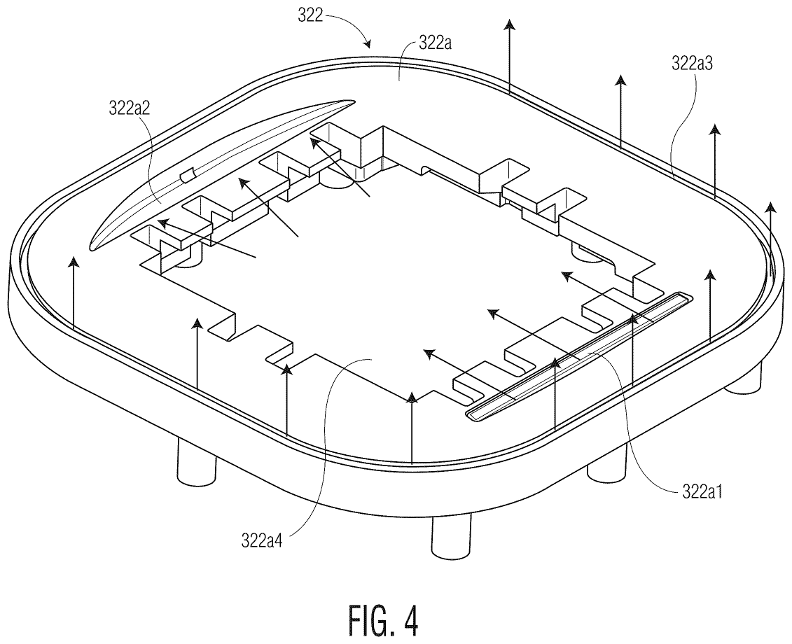

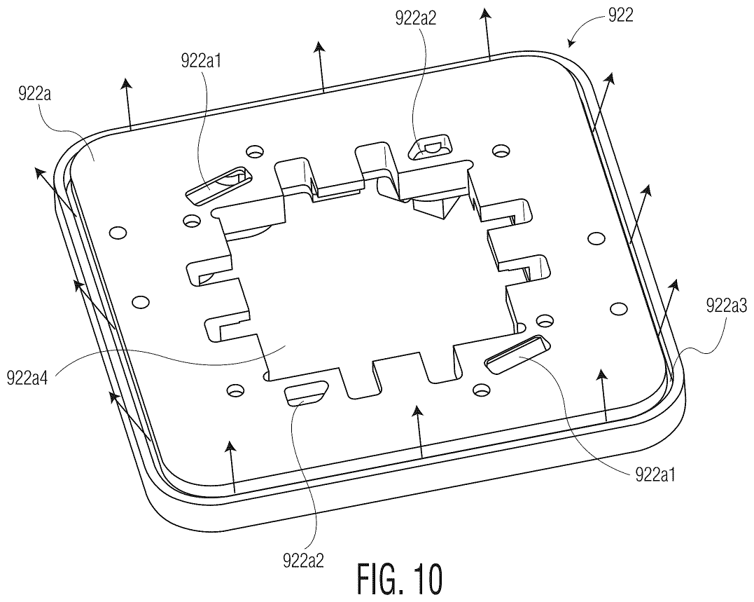

It is contemplated that the invention is useful in a variety of applications (e.g., in connection with various semiconductor element types, various bonding types, etc.). As such, different configurations including various attributes are described herein. For example, it may be desirable to include various shielding gas profiles, increase reducing gas concentration/flow rate, increase recapture of exhaust, manipulate fluid flow, etc. FIGS. 4-9 are described with reference to the straight across flow configuration. FIGS. 10-15 are described with reference to the impinging flow configuration.

In FIG. 4, a manifold 322 is illustrated. Manifold 322 includes a lower surface 322a. Lower surface 322a defines a reducing gas port 322a1, an exhaust port 322a2, a shielding gas port 322a3, and an opening 322a4. Reducing gas port 322a1 is located on an opposite side of lower surface 322a from exhaust port 322a2. Both of reducing gas port 322a1 and exhaust port 322a2 are single, wide slots (e.g., over 50% of the width of manifold 322). Shielding gas port 322a3 is configured to provide a curtain of shielding gas that surrounds the bonding area.

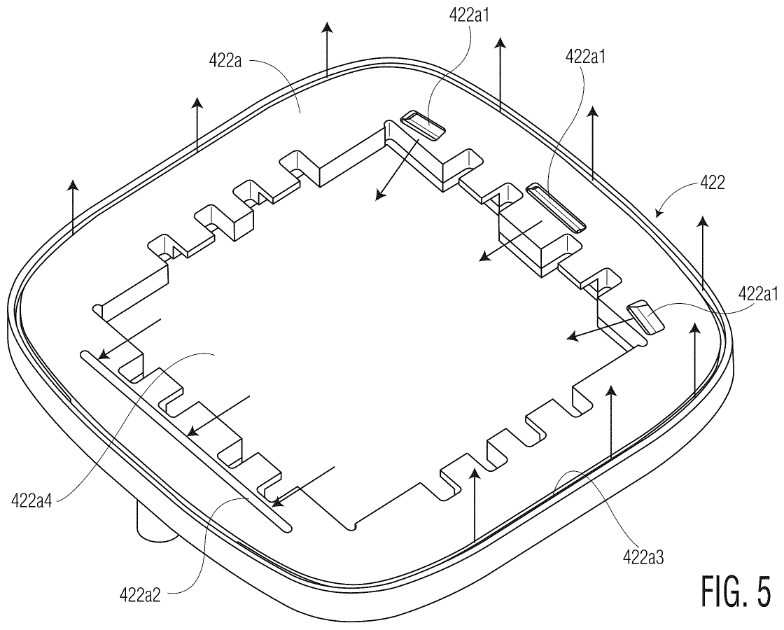

FIG. 5 illustrates a manifold 422. Manifold 422 includes a lower surface 422a. Lower surface 422a defines a plurality of reducing gas ports 422a1, an exhaust port 422a2, a shielding gas port 422a3, and an opening 422a4. The plurality of reducing gas ports 422a1 is located on an opposite side of lower surface 422a from exhaust port 422a2. Each of the plurality of reducing gas ports 422a1 is a short slot (e.g., under 25% of the width of manifold 422). The plurality of reducing gas ports 422a1 are arranged along a curve such that the outer reducing gas ports project inward toward the center of manifold 422. Shielding gas port 422a3 is configured to provide a curtain of shielding gas that surrounds the bonding area.

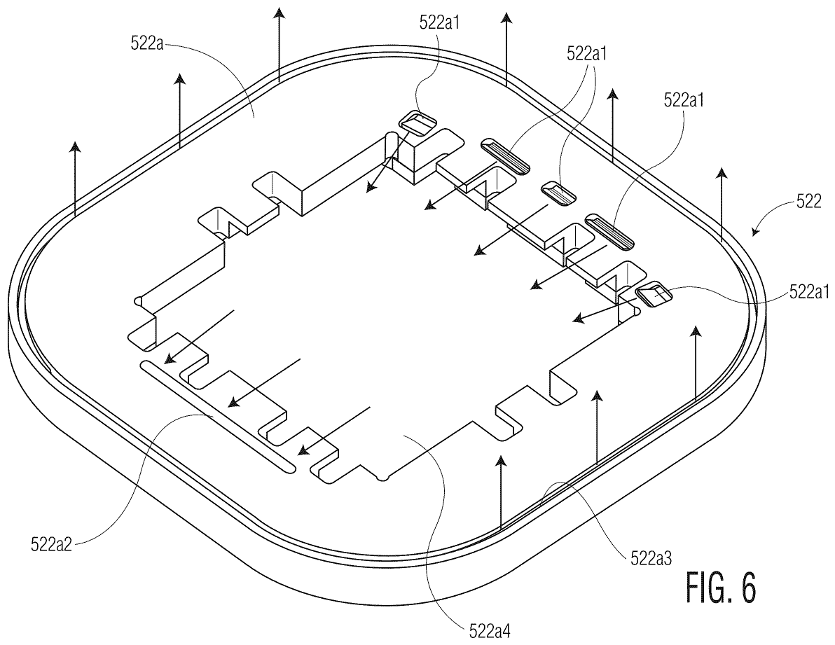

FIG. 6 illustrates a manifold 522. Manifold 522 includes a lower surface 522a. Lower surface 522a defines a plurality of reducing gas ports 522a1, an exhaust port 522a2, a shielding gas port 522a3, and an opening 522a4. The plurality of reducing gas ports 522a1 are located on an opposite side of lower surface 522a from exhaust port 522a2. Three of the plurality of reducing gas ports 522a1 are arranged along a straight line (e.g., the middle three). Shielding gas port 522a3 is configured to provide a curtain of shielding gas that surrounds the bonding area. Although FIGS. 4-6 illustrate 1, 3, and 5 reducing gas ports, respectively, the invention is not limited to any particular number of reducing gas ports.

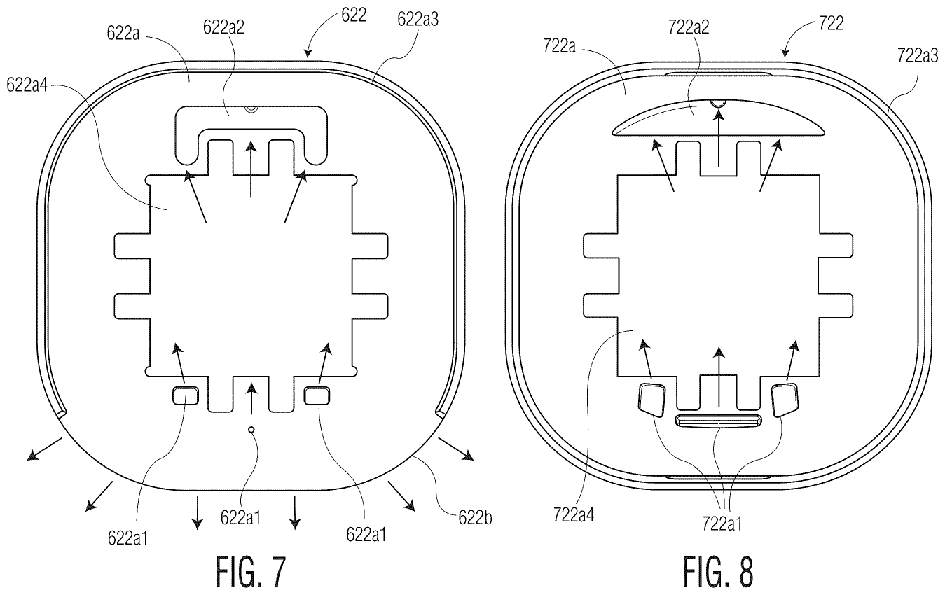

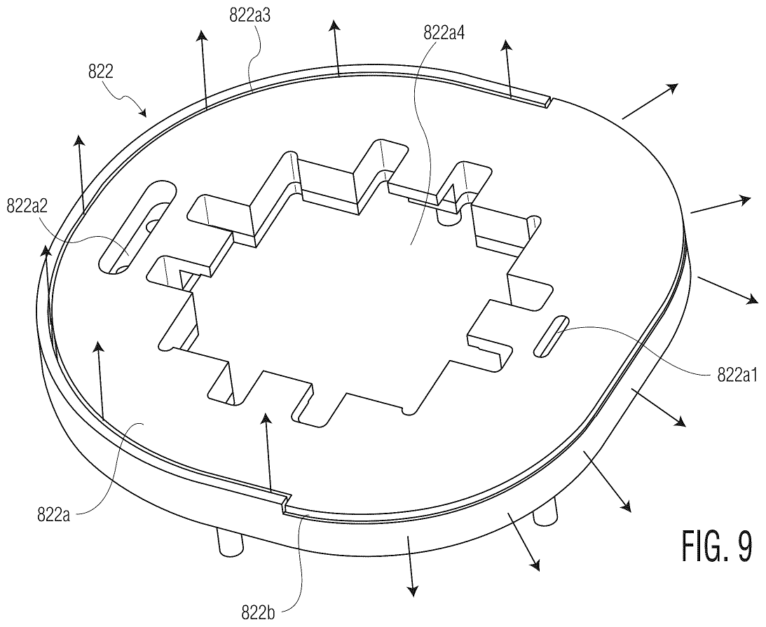

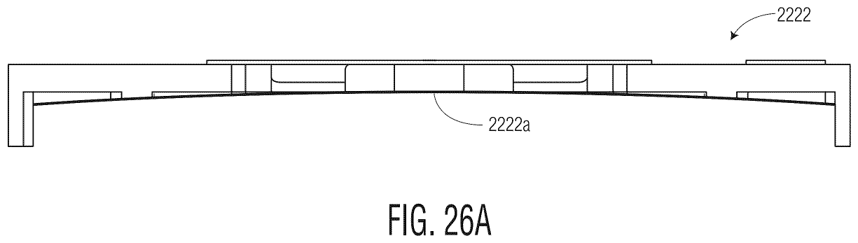

FIG. 7 illustrates a manifold 622. Manifold 622 includes a lower surface 622a. Lower surface 622a defines a plurality of reducing gas ports 622a1, an exhaust port 622a2, a shielding gas port 622a3, and an opening 622a4. The plurality of reducing gas ports 622a1 are located on an opposite side of lower surface 622a from exhaust port 622a2. Two of the plurality of reducing gas ports 622a1 are short slots, and another of the plurality of reducing gas ports 622a1 is a circular hole. Exhaust port 622a2 has a “horseshoe” shape. Shielding gas port 622a3 is configured to provide a curtain of shielding gas that partially surrounds the bonding area. Manifold 622 also includes a shielding gas port 622b that is configured to provide a curtain of shielding gas in a lateral direction (e.g., see FIGS. 9 and 25 for additional detail).

FIG. 8 illustrates a manifold 722. Manifold 722 includes a lower surface 722a. Lower surface 722a defines a plurality of reducing gas ports 722a1, an exhaust port 722a2, a shielding gas port 722a3, and an opening 722a4. The plurality of reducing gas ports 722a1 are located on an opposite side of lower surface 722a from exhaust port 722a2. The plurality of reducing gas ports 722a1 includes a short slot and two quadrilateral-shaped openings with an aspect ratio of approximately 1. Exhaust port 722a2 has the shape of a segment of an oval. Shielding gas port 722a3 is configured to provide a curtain of shielding gas that surrounds the bonding area.

FIG. 9 illustrates a manifold 822. Manifold 822 includes a lower surface 822a. Lower surface 822a defines a reducing gas port 822a1, an exhaust port 822a2, a shielding gas port 822a3, and an opening 822a4. Both reducing gas port 822a1 and exhaust port 822a2 are short slots. Shielding gas port 822a3 is configured to provide a curtain of shielding gas that partially surrounds the bonding area. Manifold 822 also includes a shielding gas port 822b that is configured to provide a curtain of shielding gas in a lateral direction. Shielding gas port 822b is contiguous with shielding gas port 822a3; however, the invention is not limited to such.

FIG. 10 illustrates a manifold 922. Manifold 922 includes a lower surface 922a. Lower surface 922a defines a plurality of reducing gas ports 922a1, a plurality of exhaust ports 922a2, a shielding gas port 922a3, and an opening 922a4. One of the plurality of reducing gas ports 922a1 is located on an opposite side of lower surface 922a from another of the plurality of reducing gas ports 922a1. Each of the plurality of reducing gas ports 922a1 is a short slot and is located proximate to a corner of opening 922a4 (e.g., located within 25% of the width of opening 922a4 from the corner of opening 922a4). Each of the plurality of exhaust ports 922a2 is on a side adjacent to each of the plurality of reducing gas ports 922a1, e.g., each of the plurality of exhaust ports 922a2 is located proximate to a corner of opening 922a4 not occupied by one of the plurality of reducing gas ports 922a1. Shielding gas port 922a3 is configured to provide a curtain of shielding gas that surrounds the bonding area.

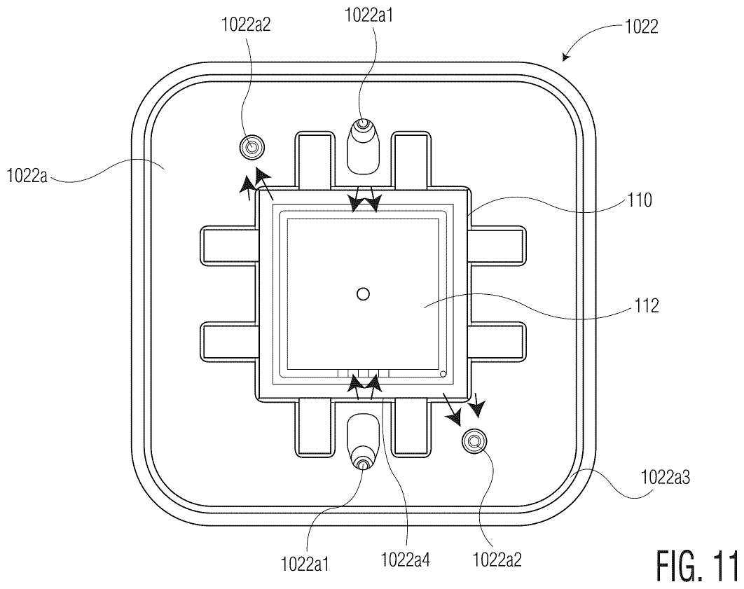

FIG. 11 illustrates a manifold 1022. Manifold 1022 includes a lower surface 1022a. Lower surface 1022a defines a plurality of reducing gas ports 1022a1, a plurality of exhaust ports 1022a2, a shielding gas port 1022a3, and an opening 1022a4. One of the plurality of reducing gas ports 1022a1 is located on an opposite side of lower surface 1022a from another of the plurality of reducing gas ports 1022a1. Each of the plurality of exhaust ports 1022a2 is adjacent to one of the plurality of reducing gas ports 1022a1 (e.g., located on the same side of lower surface 1022a). Shielding gas port 1022a3 is configured to provide a curtain of shielding gas that surrounds the bonding area. Opening 1022a4 is illustrated as being occupied by bonding tool 110 and semiconductor element 112.

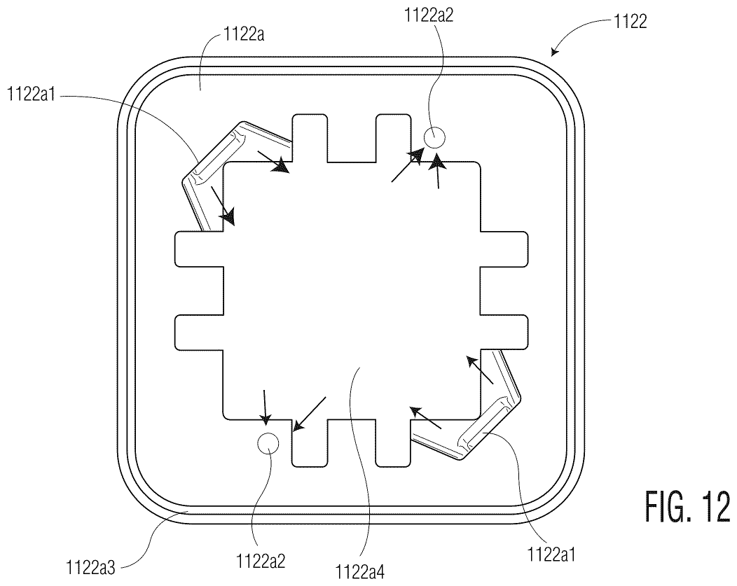

FIG. 12 illustrates a manifold 1122. Manifold 1122 includes a lower surface 1122a. Lower surface 1122a defines a plurality of reducing gas ports 1122a1, a plurality of exhaust ports 1122a2, a shielding gas port 1122a3 and an opening 1122a4. One of the plurality of reducing gas ports 1122a1 is located on an opposite side of lower surface 1122a from another of the plurality of reducing gas ports 1122a1. In particular, the reducing gas ports are located on opposing corners of opening 1122a4 (e.g., located within 25% of a width of opening 1122a4 from the corner of opening 1122a4). Each of the plurality of exhaust ports 1122a2 is located at a corner of opening 1122a4 adjacent to the corner occupied by one of the plurality of reducing gas ports 1122a1. Each of the plurality of exhaust ports 1122a2 is a circular opening in lower surface 1122a.

FIG. 13 illustrates a manifold 1222. Manifold 1222 includes a lower surface 1222a. Lower surface 1222a defines a plurality of reducing gas ports 1222a1, a plurality of exhaust ports 1222a2, a shielding gas port 1222a3, and an opening 1222a4. Each of the plurality of reducing gas ports 1222a1 is a circular opening in lower surface 1222a. The plurality of reducing gas ports 1222a1 is arranged at equally spaced intervals around opening 1222a4 (as illustrated, each is centered on a side of opening 1222a4). Each of the plurality of exhaust ports 1222a2 is a circular opening in lower surface 1222a. The plurality of exhaust ports 1222a2 are arranged at equal intervals around opening 1222a4 (as illustrated, each exhaust port is at a corner of opening 1222a4). Opening 1222a4 is illustrated as being occupied by bonding tool 110 and semiconductor element 112.

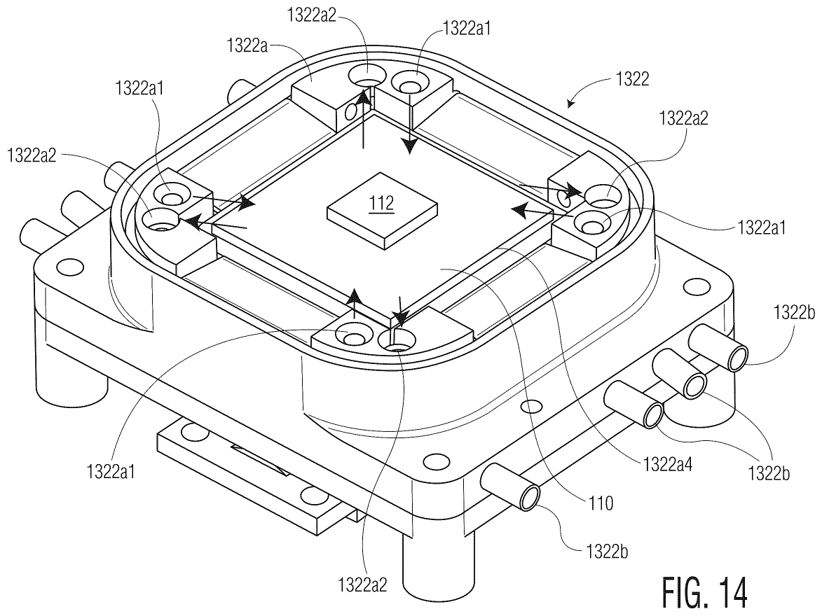

FIG. 14 illustrates a manifold 1322. Manifold 1322 includes a lower surface 1322a. Lower surface 1322a defines a plurality of reducing gas ports 1322a1, a plurality of exhaust ports 1322a2, and an opening 1322a4. Lower surface 1322a is not a contiguous surface, but has four disparate sections, each section located at a corner of opening 1322a4. Each section of lower surface 1322a defines one of the plurality of reducing gas ports 1322a1 and one of the plurality of exhaust ports 1322a2. Opening 1322a4 is illustrated as being occupied by bonding tool 110 and semiconductor element 112. FIG. 14 also illustrates a plurality of inlets for respective fluids provided to manifold 1322 (e.g., see various inlets 1322b described in connection with FIG. 1). The inlets may be coupled with, for example, a reducing gas source, a vacuum source, and/or an inert gas source (e.g., coupled via flexible tubing).

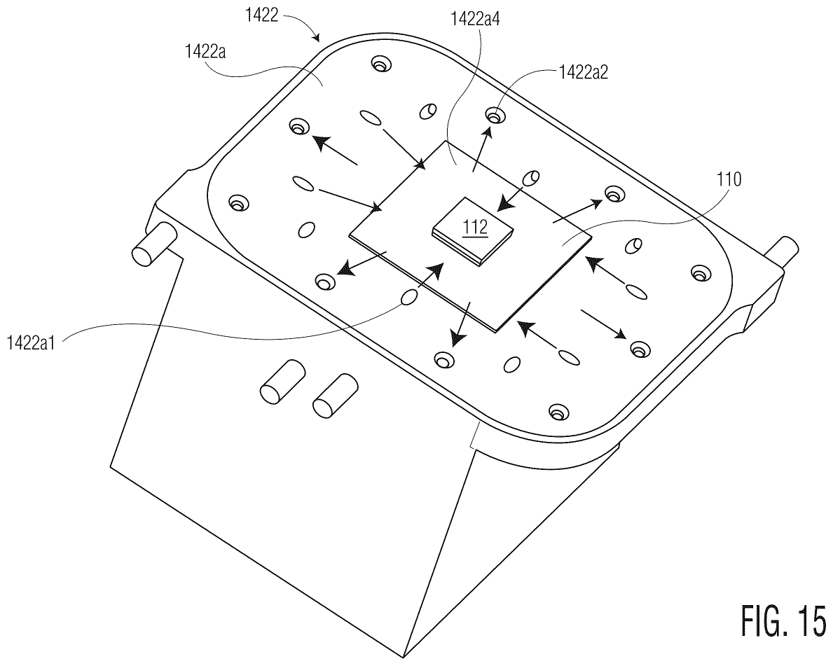

FIG. 15 illustrates a manifold 1422. Manifold 1422 includes a lower surface 1422a. Lower surface 1422a defines a plurality of reducing gas ports 1422a1, a plurality of exhaust ports 1422a2, and an opening 1422a4. Each of the plurality of reducing gas ports 1422a1 is an ovular opening in lower surface 1422a. The plurality of reducing gas ports 1422a1 are arranged around opening 1422a4, with six of the plurality of reducing gas ports 1422a1 opposing each other along one axis (e.g., three on one side of opening 1422a4 and three on the other) and four of the plurality of reducing gas ports 1422a1 opposing each other along another axis (e.g., two on one side of opening 1422a4 and two on the other). Some arrows are omitted for clarity. Each of the plurality of exhaust ports 1422a2 is a circular opening in lower surface 1422a. The plurality of exhaust ports 1422a2 are arranged around opening 1422a4, with one of the plurality of exhaust ports 1422a2 aligned with each corner of opening 1422a4 (e.g., accounting for four exhaust ports). An additional two of the plurality of exhaust ports 1422a2 are provided on each side of opening 1422a4 having three of the plurality of reducing gas ports 1422a1. An additional one of the plurality of exhaust ports 1422a2 is provided on each side of opening 1422a4 having two of the plurality of reducing gas ports 1422a1. Some arrows are omitted for clarity. Opening 1422a4 is illustrated as being occupied by bonding tool 110 and semiconductor element 112.

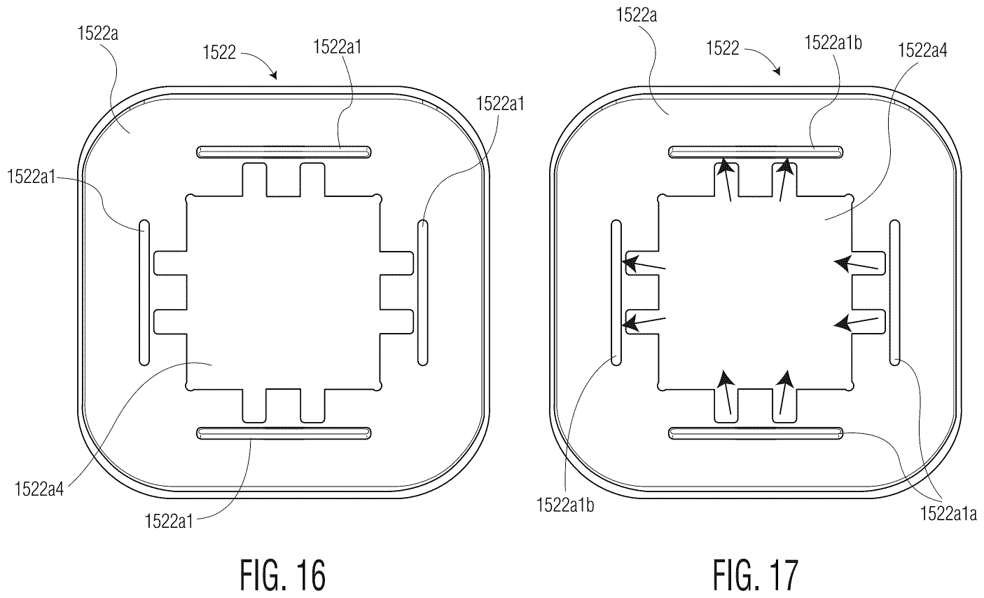

Each of FIGS. 2-15 have been described with respect to various manifold shapes, port arrangements, port geometries, etc. However, it is contemplated that other attributes may be desirable in various applications of the invention. Other aspects of the invention are described herein. In particular, FIGS. 16-19 illustrate selectable ports (described herein), and FIGS. 20A-20E, 21A, 21B, 22-25, 26A, and 26B illustrate various manifold characteristics for manipulating the flow of the various fluids distributed by the manifold. For example, any of the characteristics of a manifold described in connection with FIGS. 20A-20E, 21A, 21B, 22-25, 26A, and 26B may be incorporated into any manifold described herein, or otherwise within the scope of the invention.

Referring specifically to FIG. 16, a manifold 1522 is provided. Manifold 1522 includes a lower surface 1522a. Lower surface 1522a defines a plurality of selectable ports 1522a1 and an opening 1522a4. Each of the plurality of selectable ports 1522a1 is configured to be either an input port (i.e., to provide reducing gas to the bonding area), or an exhaust port (i.e., to remove exhaust from the bonding area (e.g., via vacuum)). Selection may occur, for example, by coupling each of the plurality of selectable ports 1522a1 to an appropriate (i) reducing gas supply or (ii) exhaust (e.g., see “REDUCING GAS IN” and “EXHAUST OUT” in FIG. 1). It is also contemplated that selection could occur via valving included in manifold 1522 (e.g., wherein such valving is controlled manually or by an electronic controller).

FIGS. 17-19 illustrate various arrangements of a manifold with selectable ports. Specifically, FIG. 17 illustrates manifold 1522 with two adjacent ports as selected input ports 1522a1a (e.g., the right and lower ports, as illustrated), and the other two adjacent ports as selected exhaust ports 1522a1b (e.g., the left and upper ports, as illustrated). In the configuration illustrated in FIG. 17, manifold 1522 has a dual straight across flow configuration (i.e., each input port directs flow straight across opening 1522a4 toward an exhaust port).

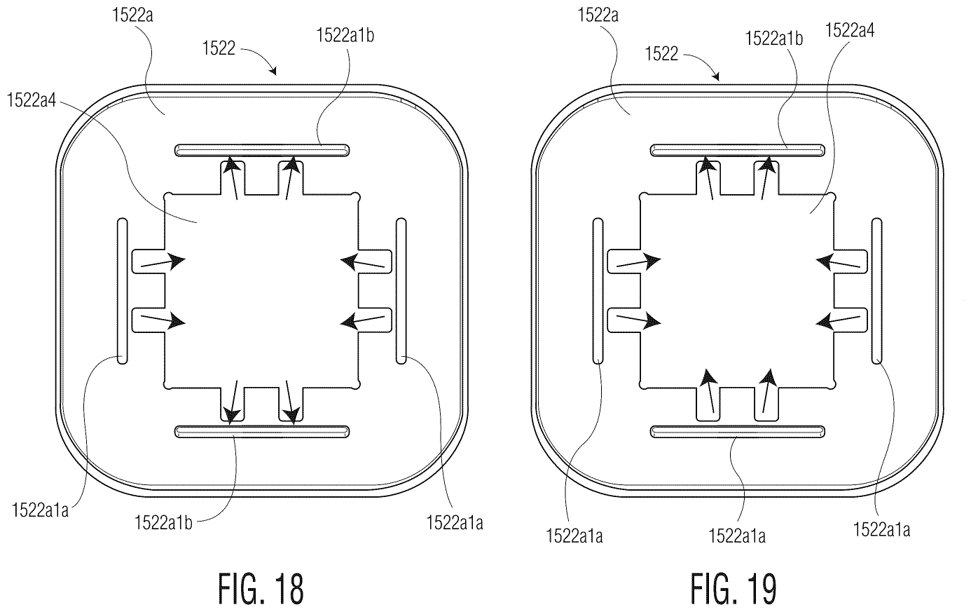

FIG. 18 illustrates manifold 1522 with two opposing ports as selected input ports 1522a1a (e.g., the left and right ports, as illustrated) and the other two opposing ports as selected exhaust ports 1522a1b (e.g., the upper and lower ports, as illustrated). In FIG. 18, manifold 1522 has an impinging flow configuration.

FIG. 19 illustrates manifold 1522 with the ports on three sides of opening 1522a4 as selected input ports 1522a1a (e.g., the left, right, and lower ports, as illustrated) and the port on the fourth side of opening 1522a4 as the selected exhaust port 1522a1b (e.g., the upper port, as illustrated).

Although FIGS. 17-19 are described with reference to a manifold with selectable ports, these embodiments are not limited to such. It is contemplated that the embodiments could be implemented with a fixed-port manifold, i.e., a manifold that does not include selectable ports. Further, it is contemplated that any configuration of input and exhaust ports may be used within the scope of the invention. It is further contemplated that any of the selectable ports could be used to provide shielding gas or be left unselected. Further still, it is contemplated that selectable ports could have any shape, and it is contemplated that each side of the manifold may include a plurality of selectable ports, or a combination of selectable and fixed ports.

FIGS. 20A-20E illustrate portions of a manifold 1622. Manifold 1622 includes a lower surface 1622a that defines a reducing gas port 1622a1 and an exhaust port (not illustrated). FIG. 20A is a close up bottom view of reducing gas port 1622a1. FIG. 20B is a cut away view of manifold 1622 along the line labeled “FIG. 20B” in FIG. 20A, allowing a perspective inside of manifold 1622. Manifold 1622 includes a flow steering protrusion 1622b1 proximate to reducing gas port 1622a1 for steering the reducing gas inside of the manifold. FIG. 20C is a top view from the perspective of the arrow labeled “FIG. 20C, 20D” in FIG. 20B. Reducing gas is directed toward flow steering protrusion 1622b1. Flow steering protrusion 1622b1 directs the reducing gas radially away from flow steering protrusion 1622b1 such that the reducing gas is distributed across reducing gas port 1622a1.

FIG. 20D is a top view from the perspective of the arrow labeled “FIG. 20C, 20D” in FIG. 20B (i.e., the same perspective as FIG. 20C, however, flow steering protrusion 1622b1 has been omitted for clarity). Manifold 1622 defines a plurality of flow steering grooves and/or protrusions 1622a2 proximate to reducing gas port 1622a1 for steering the reducing gas inside of manifold 1622. Although each of the plurality of flow steering grooves and/or protrusions 1622a2 is illustrated as having a curved shape, the invention is not limited, as it is contemplated that a flow steering groove or protrusion could have any shape and still be within the scope of the invention. A flow steering groove and/or protrusion may also be used proximate to an exhaust port.

FIG. 20E is a close up view of the content within the circle labeled “FIG. 20E” in FIG. 20B. Manifold 1622 defines a variable port gap 1622b2 proximate to reducing gas port 1622a1. Variable port gap 1622b2 is narrower at the outer portions of reducing gas port 1622a1 and wider toward the center of reducing gas port 1622a1. While FIG. 20E illustrates variable port gap 1622b2 as having an ovular profile, the invention is not limited to such. It is contemplated that a variable port gap could have any profile, including a profile that is circular, V-shaped, parabolic, stepped, etc.

Although manifold 1622 is illustrated and described as including all of the features described in connection with FIGS. 20A-20E, the invention is not intended to be limited to including all of these features. It is contemplated that a manifold could include any combination of the described features.

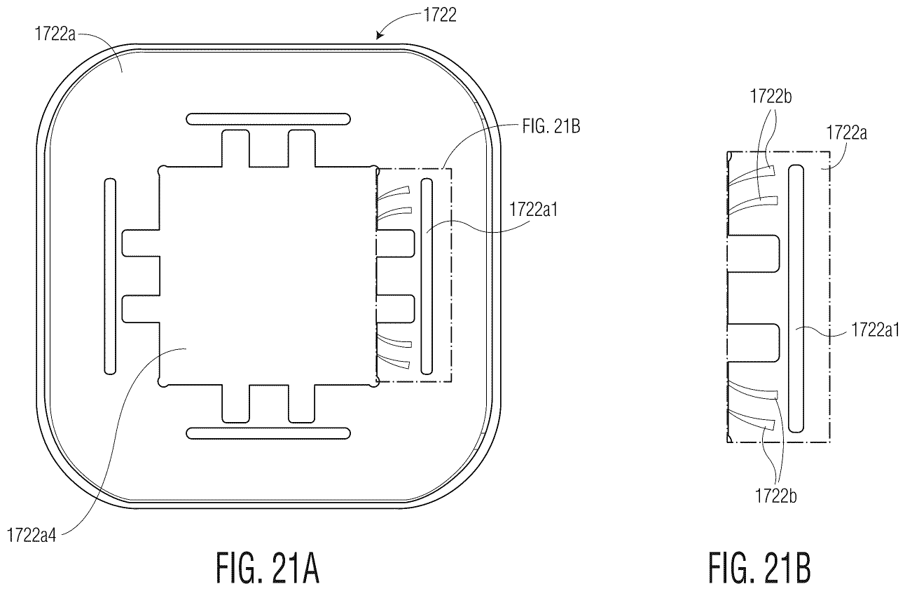

FIG. 21A illustrates a manifold 1722, and FIG. 21B is a detailed view of a portion of FIG. 21A. Manifold 1722 includes a lower surface 1722a, which defines a reducing gas port 1722a1 and an opening 1722a4. Lower surface 1722a defines a plurality of flow steering protrusions and/or grooves 1722b proximate to reducing gas port 1722a1 for steering the reducing gas. Although each of the plurality of flow steering grooves and/or protrusions 1722b is illustrated as having a curved shape, the invention is not limited, as it is contemplated that a flow steering groove or protrusion could have any shape and still be within the scope of the invention. A flow steering groove and/or protrusion may also be used proximate to an exhaust port.

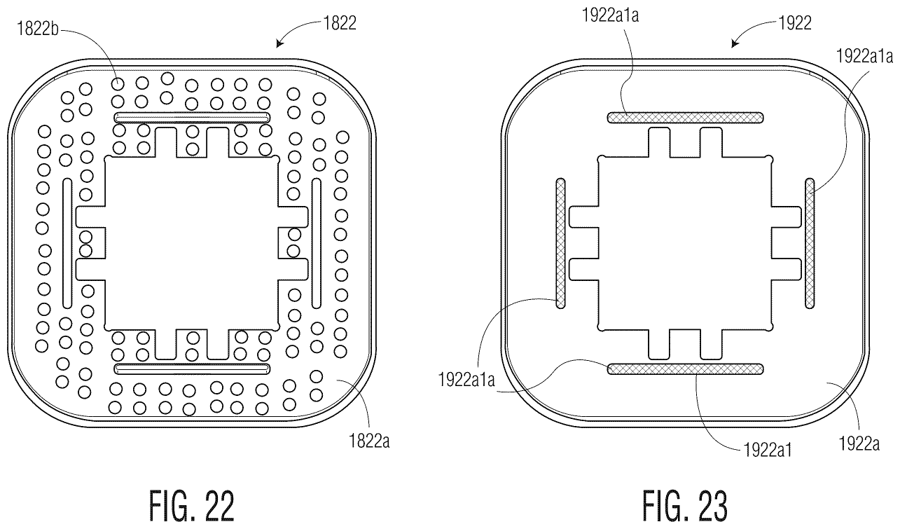

FIG. 22 illustrates a manifold 1822. Manifold 1822 includes a lower surface 1822a, which defines a plurality of dimples and/or pimples 1822b. Such dimples and/or pimples 1822b may induce turbulence in the reducing gas. Although dimples/pimples 1822b are shown in a particular configuration and number, the invention is not limited to such, as any configuration or number is contemplated for tuning the flow characteristics of the reducing gas, shielding gas, and/or reaction products. It is further contemplated that dimples/pimples may be included on other surfaces of manifold 1822, including the sides and top surfaces.

FIG. 23 illustrates a manifold 1922. Manifold 1922 includes a lower surface 1922a, which defines a plurality of ports 1922a1 for providing reducing gas and/or removing reaction products. Each port 1922a1 includes a screen 1922a1a disposed therein. Each screen 1922a1a may be used to induce turbulence in the fluid flowing through the respective port 1922a1. Exemplary screens 1922a1a include mesh screens, porous materials, etc.

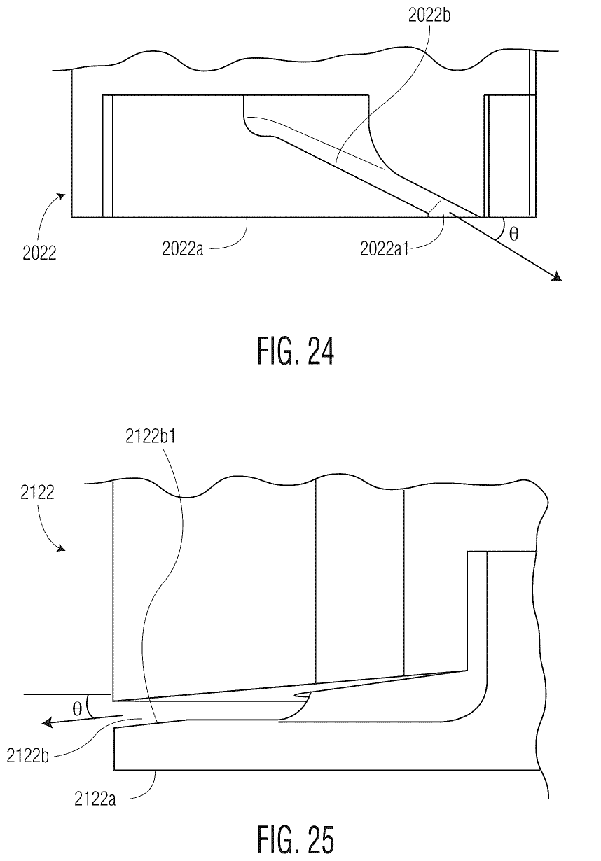

FIG. 24 illustrates a manifold 2022. Manifold 2022 includes a lower surface 2022a, which defines a reducing gas port 2022a1. Manifold 2022 includes an angled surface 2022b proximate to reducing gas port 2022a1 for directing flow of the reducing gas at an angle θ from the horizontal.

FIG. 25 illustrates a manifold 2122. Manifold 2122 includes a lower surface 2122a and a shielding gas port 2122b. Shielding gas port 2122b includes an angled surface 2122b1 direct a shielding gas outward from manifold 2122 at an angle θ from the horizontal (e.g., see manifold 622 of FIG. 7, manifold 822 of FIG. 9, etc.).

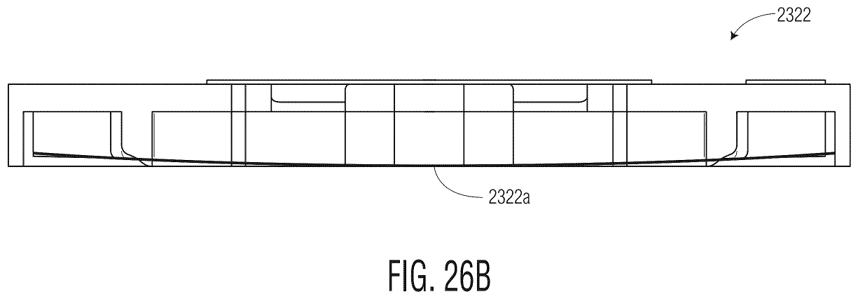

FIG. 26A illustrates a manifold 2222 that includes a concave lower surface 2222a. Concave lower surface 2222a may include any number or arrangement of ports (e.g., any of the configurations illustrated and described in FIGS. 2-19). FIG. 26B illustrates a manifold 2322 that includes a convex lower surface 2322a. Convex lower surface 2322a may include any number or arrangement of ports (e.g., any of the configurations illustrated and described in FIGS. 2-19). Implementing a convex or concave lower surface may improve attributes such as reducing gas concentration at the bonding area or recapture of reducing gas and/or exhaust.

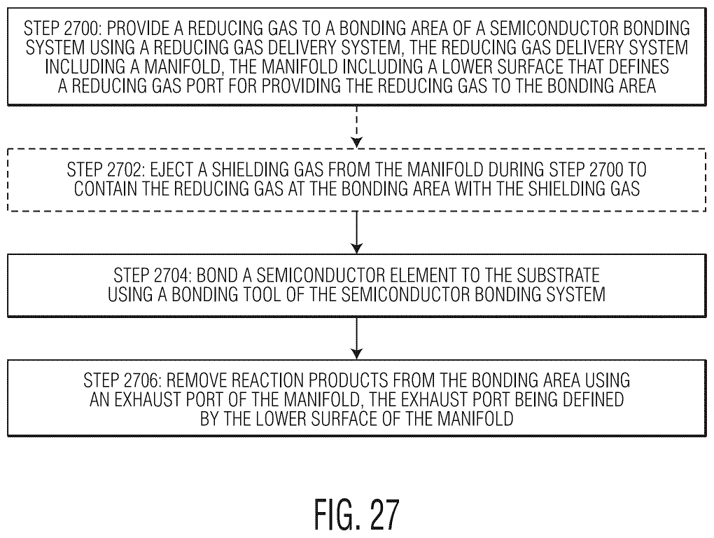

FIG. 27 is a flow diagram illustrating various methods of bonding a semiconductor element to a substrate on a bonding system. As is understood by those skilled in the art, certain steps included in the flow diagram may be omitted; certain additional steps may be added, and the order of the steps may be altered from the order illustrated-all within the scope of the invention.

At Step 2700, a reducing gas is provided to a bonding area of a semiconductor bonding system using a reducing gas delivery system (e.g., see reducing gas delivery system 120 in FIG. 1); the reducing gas delivery system includes a manifold (e.g., manifold 122, 222, . . . , 2322), the manifold including a lower surface that defines a reducing gas port (e.g., reducing gas port 122a1, 222a1, . . . , 2022a1) for providing the reducing gas to the bonding area. During Step 2700, the reducing gas may be provided in a state of turbulent flow, for example, the turbulence being induced by a plurality of dimples defined by the lower surface (e.g., see dimples/pimples 1822b in FIG. 22). At optional Step 2702, a shielding gas is ejected from the manifold during Step 2700 (e.g., from shielding gas port 122a3, 222a3, shielding gas port 622b, shielding gas port 822b, shielding gas port 2122b, etc.) to contain the reducing gas at the bonding area with the shielding gas.

At Step 2704, a semiconductor element is bonded to the substrate using a bonding tool of the bonding system. Steps 2700 and 2704 may occur separately (e.g., Step 2700 is completed prior to starting Step 2704), may occur simultaneously, or may partially overlap each other in time.

At Step 2706, reaction products are removed from the bonding area using an exhaust port of the manifold, the exhaust port being defined by the lower surface of the manifold (e.g., exhaust port 122a2, 222a2, . . . , 1422a2, etc.).

Each of Steps 2700, 2702, 2704, and 2706 may occur separately, simultaneously, or may partially overlap each other in time. For example, in a straight across flow configuration it would be advantageous for Steps 2700 and 2706 to occur simultaneously, such that during Step 2700 the reducing gas is directed across the bonding area (e.g., wherein the reducing gas port is positioned on an opposite side of the lower surface from the exhaust port, as in, for example, FIGS. 2, and 4-9).

Alternatively, in an impinging flow configuration, Step 2700 includes providing the reducing gas to the bonding area via a plurality of reducing gas ports defined by the lower surface, with one of the plurality of reducing gas ports being located on an opposite side of the lower surface from another of the plurality of reducing gas ports. In such a configuration, it may increase the concentration of reducing gas at the bonding area to perform Step 2706 after Step 2700 and/or Step 2704 is completed.

Although the invention has been described and illustrated with respect to the exemplary embodiments thereof, it should be understood by those skilled in the art that the foregoing and various other changes, omissions, and additions may be made therein and thereto, without parting from the spirit and scope of the present invention. Rather, various modifications may be made in the details within the scope and range of equivalents of the claims and without departing from the invention.

1. A bonding system for bonding a semiconductor element to a substrate, the bonding system comprising:
a bond head assembly including a bonding tool configured for bonding the semiconductor element to the substrate; and
a reducing gas delivery system for providing a reducing gas to a bonding area of the bonding system, the reducing gas delivery system including a manifold, the manifold including a lower surface defining (i) a reducing gas port for providing the reducing gas to the bonding area, and (ii) an exhaust port for removing a reaction product from the bonding area.

2. The bonding system of claim 1 wherein the reducing gas port is on an opposite side of the lower surface from the exhaust port.

3. The bonding system of claim 1 wherein the lower surface defines a plurality of reducing gas ports for providing the reducing gas to the bonding area, the reducing gas port being one of the plurality of reducing gas ports.

4. The bonding system of claim 3 wherein the plurality of reducing gas ports are on an opposite side of the lower surface from the exhaust port.

5. The bonding system of claim 3 wherein one of the plurality of reducing gas ports is located on an opposite side of the lower surface from another of the plurality of reducing gas ports.

6. The bonding system of claim 5 wherein the exhaust port is adjacent to at least one of the plurality of reducing gas ports.

7. The bonding system of claim 3 wherein the plurality of reducing gas ports are arranged on three sides of an opening defined by the lower surface, and the exhaust port is located on a fourth side of the opening.

8. The bonding system of claim 3 wherein the plurality of reducing gas ports are arranged along a line.

9. The bonding system of claim 3 wherein the plurality of reducing gas ports are arranged along a curve.

10. The bonding system of claim 1 wherein the lower surface defines a plurality of exhaust ports for removing the reaction product from the bonding area, the exhaust port being one of the plurality of exhaust ports.

11. The bonding system of claim 1 wherein the reducing gas port is located on a corner of the lower surface.

12. The bonding system of claim 11 wherein the exhaust port is located on another corner of the lower surface.

13. The bonding system of claim 1 wherein the reducing gas delivery system is integrated with the bond head assembly.

14. The bonding system of claim 1 wherein the manifold defines an opening to accommodate the bonding tool.

15-23. (canceled)

24. A reducing gas delivery system of a bonding system comprising:
a manifold for (i) providing a reducing gas to a bonding area of the bonding system and (ii) removing a reaction product from the bonding area of the bonding system, the manifold including a lower surface;
a reducing gas port for delivering the reducing gas to the bonding area, the reducing gas port being at least partially defined by the lower surface of the manifold; and
an exhaust port for removing the reaction product from the bonding area, the exhaust port being at least partially defined by the lower surface of the manifold.

25. The reducing gas delivery system of claim 24 wherein the reducing gas port is on an opposite side of the lower surface from the exhaust port.

26. The reducing gas delivery system of claim 24 wherein the lower surface defines a plurality of reducing gas ports for providing the reducing gas to the bonding area, the reducing gas port being one of the plurality of reducing gas ports.

27. The reducing gas delivery system of claim 26 wherein one of the plurality of reducing gas ports is located on an opposite side of the lower surface from another of the plurality of reducing gas ports.

28. A method of bonding a semiconductor element to a substrate on a bonding system, the method comprising the steps of:
(a) providing a reducing gas to a bonding area of the bonding system using a reducing gas delivery system, the reducing gas delivery system including a manifold, the manifold including a lower surface that defines a reducing gas port for providing the reducing gas to the bonding area;
(b) bonding the semiconductor element to the substrate using a bonding tool of the bonding system; and
(c) removing reaction products from the bonding area using an exhaust port of the manifold, the exhaust port being defined by the lower surface of the manifold.

29. The method of claim 28 wherein step (a) includes providing the reducing gas to the bonding area in a state of turbulent flow, the state of turbulent flow being induced by a plurality of dimples defined by the lower surface.

30.-35. (canceled)
